(19) United States
(12) Patent Application Publication
(10) Pub. No.: US 2018/0076324 A1
(43) Pub. Date: Mar. 15, 2018

(54) METHOD OF CONTACT FORMATION BETWEEN METAL AND SEMICONDUCTOR

(71) Applicant: Applied Materials, Inc., Santa Clara, CA (US)

(72) Inventors: Yi-Chiau HUANG, Fremont, CA (US); Hua CHUNG, San Jose, CA (US); Xuebin LI, Sunnyvale, CA (US)

(21) Appl. No.: 15/414,080

(22) Filed: Jan. 24, 2017

Related U.S. Application Data
(60) Provisional application No. 62/394,399, filed on Sep. 14, 2016.

(51) Int. Cl. H01L 29/78; H01L 29/08; H01L 29/66; H01L 29/165

(52) U.S. Cl. CPC H01L 29/7839; H01L 29/165; H01L 29/66643; H01L 29/0847

(57) ABSTRACT

Implementations of the present disclosure generally relate to improved semiconductor devices and methods of manufacture thereof. More specifically, implementations disclosed herein relate to a semiconductor device having an improved contact interface between the semiconductor material and metal material and methods of manufacture thereof. The method includes forming a semiconductor layer on a silicon substrate, forming an interfacial layer over the semiconductor layer, and forming a metal contact layer over the interfacial layer. The interfacial layer comprises one or more of germanium, boron, gallium, indium, thallium, arsenic, antimony, tin, silicon, and phosphorus, and has a thickness of between about 50 angstroms and about 100 angstroms. The interfacial layer improves the quality of the contact interface between the semiconductor material and metal material.

### CROSS-REFERENCE TO RELATED APPLICATIONS

This application claims benefit of U.S. Provisional Patent Application Ser. No. 62/394,399, filed on Sep. 14, 2016, which is herein incorporated by reference in its entirety.

### BACKGROUND

### Field

Implementations of the present disclosure generally relate to manufacture of semiconductor devices. More specifically, implementations disclosed herein relate to an improved semiconductor device and method of manufacture thereof.

### Description of the Related Art

The manufacture of semiconductor devices typically includes more than four hundred process operations. Any problems encountered during processing may have a large impact on throughput and device efficiency. Problems encountered during semiconductor manufacturing include the differences in material properties of semiconductor materials and metal materials. For example, the chemical vapor deposition (CVD) of metals for silicidation, such as titanium (Ti) and tantalum (Ta) on semiconductor materials such as boron doped silicon germanium (SiGe:B) or boron-doped germanium (Ge:B), for p-type semiconductors may be hampered by material differences, such as different band engineering requirements, poor wetting, and lattice mismatch. Phosphorous-doped silicon (Si:P) for n-type semiconductors, may encounter similar problems. These material differences result in poor Ohmic contact and an increased Schottky barrier at the junction of the semiconductor material and metal material. Traditionally, the semiconductor material adjacent the metal material may be heavily doped. However, there may still be material differences between the doped semiconductor material and metal material, which result in poor contact resistivity and decreased device efficiency.

To improve device efficiency, there is a need for a semiconductor device having an improved contact interface between the semiconductor material and the metal material and a method of manufacture thereof.

### SUMMARY

In one implementation, a method of forming a device is disclosed. The method includes forming a semiconductor layer on a silicon substrate, forming an interfacial layer over the semiconductor layer, and forming a metal contact layer over the interfacial layer. The interfacial layer comprises one or more of germanium, boron, gallium, indium, thallium, arsenic, antimony, tin, silicon, and phosphorus, and has a thickness of between about 50 angstroms and about 100 angstroms.

In another implementation, a device is disclosed. The device includes a silicon substrate, a semiconductor layer contacting the silicon substrate, an interfacial layer contacting the semiconductor layer, and a metal contact layer contacting the interfacial layer. The interfacial layer comprises one or more of germanium, boron, gallium, indium, thallium, arsenic, antimony, tin, silicon, and phosphorus, and has a thickness of between about 50 angstroms and about 100 angstroms.

In yet another implementation, a device is disclosed. The device includes a silicon substrate, a first semiconductor layer and a second semiconductor layer contacting the silicon substrate, a first interfacial layer contacting the first semiconductor layer and a second interfacial layer contacting the second semiconductor layer, and a first metal contact layer contacting the first interfacial layer and a second metal contact layer contacting the second interfacial layer. The first semiconductor layer and the second semiconductor layer are separated by a channel layer. An insulating layer is contacting the channel layer and a gate layer is contacting the insulating layer. The first interfacial layer and the second interfacial layer comprise one or more of germanium, boron, gallium, indium, thallium, arsenic, antimony, tin, silicon, and phosphorus, and have a thickness of between about 50 angstroms and about 100 angstroms.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a flow diagram summarizing a method of forming a device according to one implementation described herein.

FIG. 2 illustrates a schematic sectional side view of a device structure in accordance with the method of FIG. 1 according to one implementation described herein.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Implementations of the present disclosure generally relate to improved semiconductor devices and methods of manufacture thereof. More specifically, implementations disclosed herein relate to a semiconductor device having an improved contact interface between the semiconductor material and metal material and methods of manufacture thereof. The method includes forming a semiconductor layer on a silicon substrate, forming an interfacial layer over the semiconductor layer, and forming a metal contact layer over the interfacial layer. The interfacial layer comprises one or more of germanium, boron, gallium, indium, thallium, arsenic, antimony, tin, silicon, and phosphorus, and has a thickness of between about 50 angstroms and about 100 angstroms. The interfacial layer improves the quality of the contact interface between the semiconductor material and metal material.

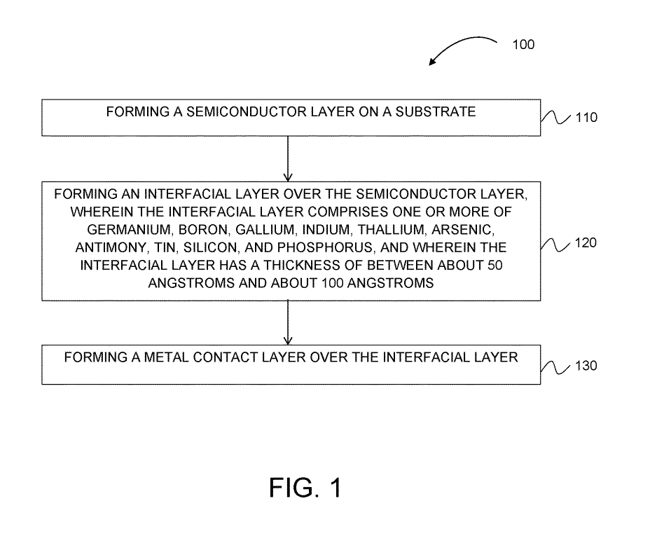

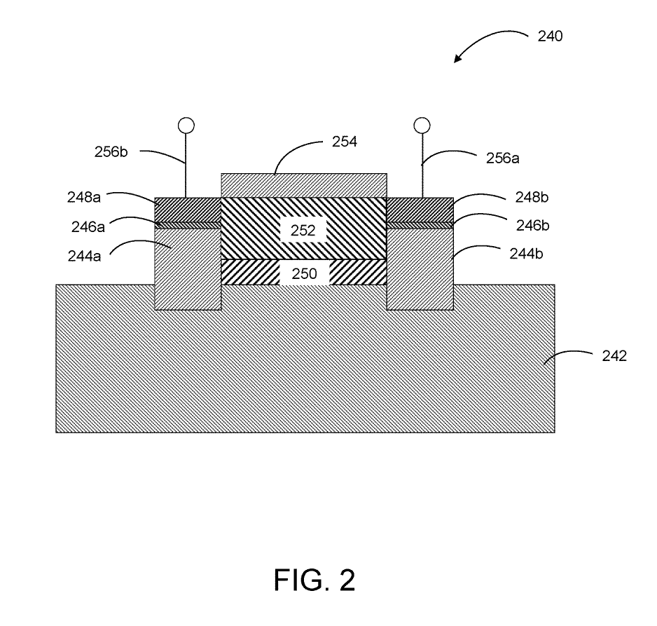

FIG. 1 illustrates a method 100 for forming a device according to one implementation described herein. FIG. 2 illustrates a schematic sectional side view of a device structure 240 in accordance with the method 100 of FIG. 1 according to one implementation described herein.

At operation 110, at least one semiconductor layer is formed over the substrate 242. In one implementation, the substrate 242 may comprise silicon. In another implementation, the substrate 242 may comprise other suitable substrate materials. As shown in FIG. 2, the device structure 240 may include a first semiconductor layer 244a, or source, and a second semiconductor layer 244b, or drain, contacting the substrate 242. In one implementation, the semiconductor layer, or the first semiconductor layer 244a and the second semiconductor layer 244b, may be disposed on and in contact with the substrate 242. In one implementation, the semiconductor layer, or the first semiconductor layer 244a and the second semiconductor layer 244b, may comprise a suitable semiconductor material for a p-type semiconductor device, such as silicon germanium (SiGe) or boron-doped silicon germanium (SiGe:B). The SiGe:B may be 50% germanium with a boron dopant concentration of 5×10²⁰ atoms/cm³. In another implementation, the semiconductor layer, or first semiconductor layer 244a and second semiconductor layer 244b, may comprise a suitable semiconductor material for an n-type semiconductor device, such as a silicon phosphide (SiP).

At operation 120, at least one interfacial layer is formed over the semiconductor layer. As shown in FIG. 2, a first interfacial layer 246a is formed over the first semiconductor layer 244a and a second interfacial layer 246b is formed over the second semiconductor layer 244b. In one implementation, the interfacial layer, shown as a first interfacial layer 246a and a second interfacial layer 246b, may comprise one or more of germanium, boron, gallium, indium, thallium, arsenic, antimony, tin, silicon, and phosphorus. In another implementation, the interfacial layer, or the first interfacial layer 246a and the second interfacial layer 246b, may comprise any other suitable interfacial material, such as other Group IV elements.

In one implementation, the first interfacial layer 246a and the second interfacial layer 246b comprise boron-doped germanium (Ge:B). During operation 120, when the interfacial layer(s) comprise(s) Ge:B, the temperature in the processing chamber is between about 300 degrees Celsius (° C.) and about 450° C. The pressure is between about 5 Torr and about 100 Torr. The total flow, which is mostly from diluent or carrier H₂ or N₂, is about 3 to about 25 standard liters per minute (slm).

In another implementation, the first interfacial layer 246a and the second interfacial layer 246b comprise boron, for example amorphous boron. This boron layer may be formed using thermal CVD of boron hydrides, boron halides, or a combination of boron hydrides and halides. During operation 120, when the interfacial layer(s) comprise(s) boron, the temperature in the processing chamber is between about 300° C. and about 600° C. The pressure is between about 10 Torr and about 80 Torr. The total flow, which is mostly from diluent or carrier H₂ or N₂, of boron precursors, including but not limited to, diborane, is about 1 to about 30 slm. The boron may diffuse or mix with the germanium or a subsequently deposited metal contact layer. In a further implementation, the first interfacial layer 246a and the second interfacial layer 246b comprising boron may be used in addition to the first interfacial layer 246a and the second interfacial layer 246b comprising Ge:B.

In yet another implementation, the first interfacial layer 246a and the second interfacial layer 246b comprise germanium tin (GeSn) or tin (Sn). During operation 120, when the interfacial layer(s) comprise(s) GeSn or Sn, the temperature in the processing chamber is between about 250° C. and about 400° C. The pressure is between about 10 Torr and about 100 Torr. The total flow, which is mostly from diluent or carrier H₂ or N₂, is about 1 to about 30 slm. In a further implementation, the first interfacial layer 246a and the second interfacial layer 246b comprising GeSn may be doped with boron such that the first interfacial layer 246a and the second interfacial layer 246b comprise GeSn:B.

In yet other implementations, the first interfacial layer 246a and the second interfacial layer 246b may comprise gallium (Ga). A suitable precursor for gallium deposition includes, but is not limited to, trimethyl gallium (TMG). For example, gallium may be formed on SiGe:B or Ge:B before deposition of a metal contact layer to improve the contact because gallium exhibits physical properties similar to potential metal contact layers and creates alloying at the interface.

In even further implementations, for example if the semiconductor is an n-type semiconductor having for example silicon phosphide (Si:P) as the semiconductor material, the first interfacial layer 246a and the second interfacial layer 246b may comprise arsenic (As) or antimony (Sb) before deposition of a metal contact layer to improve the interface.

In one implementation, the first interfacial layer 246a and the second interfacial layer 246b may have a thickness of between about 50 angstroms and about 100 angstroms. In another implementation, the first interfacial layer 246a and the second interfacial layer 246b may have a thickness of between about 1 monolayer and about 10 monolayers. In yet another implementation, the first interfacial layer 246a and the second interfacial layer 246b may have a thickness of about 1 submonolayer, or less than one monolayer. In one implementation, the first interfacial layer 246a and the second interfacial layer 246b may have a substantially uniform thickness. In another implementation, the first interfacial layer 246a and the second interfacial layer 246b may have a non-uniform thickness. In one implementation, the first interfacial layer 246a and the second interfacial layer 246b may be conformal. In another implementation, the first interfacial layer 246a and the second interfacial layer 246b may be non-conformal.

Additionally, in further implementations, the various implementations of the interfacial layer, shown as the first interfacial layer 246a and the second interfacial layer 246b in FIG. 2, may be used alone or in combination.

At operation 130, at least one metal contact layer is formed over the interfacial layer. As shown in FIG. 2, a first metal contact layer 248a is formed over the first interfacial layer 246a and a second metal contact layer 248b is formed over the second interfacial layer 246b. In one implementation, the first metal contact layer 248a and the second metal contact layer 248b may be formed by thermal chemical vapor deposition (CVD). In another implementation, the first metal contact layer 248a and the second metal contact layer 248b may be formed by sputtering during a physical vapor deposition (PVD) process.

In one implementation, the first metal contact layer 248a and the second metal contact layer 248b may comprise titanium (Ti). For example, the first metal contact layer 248a and the second metal contact layer 248b may comprise titanium nitride (TiN). A suitable precursor for titanium deposition includes, but is not limited to, titanium tetrachloride (TiCl₄).

In another implementation, the first metal contact layer 248a and the second metal contact layer 248b may comprise tantalum (Ta). Suitable precursors for tantalum deposition include, but are not limited to, tantalum tetrachloride (TaCl₄) and tantalum (V) ethoxide (Ta(OC₂H₅)₅). In further implementations, the first metal contact layer 248a and the second metal contact layer 248b may comprise other suitable metal contact materials.

Because the interfacial layer, shown as the first interfacial layer 246a and the second interfacial layer 246b, is thin, for example between about 50 angstroms and about 100 angstroms, the electrical properties at the interface between the semiconductor materials and the metal contact materials are not negatively impacted.

As shown in FIG. 2, the device structure 240 may also include a channel layer 250, which separates the first semiconductor layer 244a and the second semiconductor layer 244b. An insulating layer 252 may be disposed over the channel layer 250. In one implementation, the insulating layer 252 may be disposed on and in contact with the channel layer 250. A gate layer 254 may be disposed over the insulating layer 252. In one implementation, the gate layer 254 may be disposed on an in contact with the insulating layer 252. Additionally, the device structure 240 may include at least one probe; two are shown as probes 256a and 256b.

The method 100 may further include a post anneal. In one implementation, the method 100 may include a low-temperature post anneal. In another implementation, the method 100 may include a short-duration post anneal. In yet another implementation, the method 100 may include a pulsed post anneal.

While FIG. 2 shows a planar device structure 240 having a first semiconductor layer 244a and a second semiconductor layer 244b separated by the channel layer 250, an insulating layer 252 over the channel layer 250, and a gate layer 254 over the insulating layer, the device structure 240 may have different configurations. For example, the method 100 may be used form Fin Field Effect Transistors (FinFETs) or other devices.

Benefits of the present disclosure include, but are not limited to, adequate resistance values at the interface of the semiconductor material and metal material of a semiconductor device. For example, the contact resistivity of the device may be about 1×10⁻⁹ ohms times centimeters squared (Ωcm²). The interfacial layer allows the semiconductor material and metal material to remain in contact such that the metal material does not delaminate from the semiconductor material. The interfacial layer also results in a low Schottky barrier and thus good Ohmic contact between the semiconductor material and the metal material, which allows for increased flow of electrons from the semiconductor material through the metal contact layer and results in increased device conductivity. Moreover, the interfacial layer may result in decreased power requirements for the device. In summary, the interfacial layer may decrease resistance at the junction between the semiconductor material and metal material such that the device may have increased switching speed and thus overall increased operation speed.

While the foregoing is directed to implementations of the present disclosure, other and further implementations of the disclosure may be devised without departing from the basic scope thereof, and the scope thereof is determined by the claims that follow.

What is claimed is:

1. A method for forming a device, comprising:
forming a semiconductor layer on a silicon substrate;
forming an interfacial layer over the semiconductor layer, wherein the interfacial layer comprises one or more of germanium, boron, gallium, indium, thallium, arsenic, antimony, tin, silicon, and phosphorus, and wherein the interfacial layer has a thickness of between about 50 angstroms and about 100 angstroms; and
forming a metal contact layer over the interfacial layer.

2. The method for forming a device of claim 1, wherein the semiconductor layer is separated by a channel layer.

3. The method for forming a device of claim 2, wherein an insulating layer is deposited on the channel layer.

4. The method for forming a device of claim 3, wherein a gate layer is deposited on the insulating layer.

5. The method for forming a device of claim 1, wherein at least one probe is connected to the metal contact layer.

6. The method for forming a device of claim 4, wherein at least two probes are connected to the metal contact layer.

7. A device, comprising:
a silicon substrate;
a semiconductor layer contacting the silicon substrate;
an interfacial layer contacting the semiconductor layer, wherein the interfacial layer comprises one or more of germanium, boron, gallium, indium, thallium, arsenic, antimony, tin, silicon, and phosphorus, and wherein the interfacial layer has a thickness of between about 50 angstroms and about 100 angstroms; and
a metal contact layer contacting the interfacial layer.

8. The device of claim 7, wherein the semiconductor layer is separated by a channel layer.

9. The device of claim 8, wherein an insulating layer contacts the channel layer.

10. The device of claim 9, wherein a gate layer contacts the insulating layer.

11. The device of claim 7, wherein at least one probe is connected to the metal contact layer.

12. The device of claim 10, wherein at least two probes are connected to the metal contact layer.

13. The device of claim 7, wherein the semiconductor layer comprises SiGe or SiGeB and the interfacial layer comprises GeB.

14. A device, comprising:
a silicon substrate;
a first semiconductor layer and a second semiconductor layer contacting the silicon substrate, wherein the first semiconductor layer and the second semiconductor layer are separated by a channel layer, an insulating layer contacts the channel layer, and a gate layer contacts the insulating layer;
a first interfacial layer contacting the first semiconductor layer and a second interfacial layer contacting the second semiconductor layer, wherein the first interfacial layer and the second interfacial layer comprise one or more of germanium, boron, gallium, indium, thallium, arsenic, antimony, tin, silicon, and phosphorus, and wherein the first interfacial layer and the second interfacial layer have a thickness of between about 50 angstroms and about 100 angstroms; and
a first metal contact layer contacts the first interfacial layer and a second metal contact layer contacts the second interfacial layer.

15. The device of claim 14, further comprising a first probe connected to the first metal contact layer and a second probe connected to the second metal contact layer, wherein the first metal contact layer and the second metal contact layer comprise titanium.

16. The device of claim 14, wherein the first interfacial layer and the second interfacial layer have a thickness of between about 50 angstroms and about 100 angstroms.

17. The device of claim 14, wherein the first semiconductor layer and the second semiconductor layer comprise SiGe or SiGeB.

18. The device of claim 17, wherein the first interfacial layer and the second interfacial layer comprise GeB.

19. The device of claim 17, wherein the first interfacial layer and the second interfacial layer comprise GeSn.

20. The device of claim 14, wherein the first metal contact layer and the second metal contact layer comprise tantalum.
